(19) United States
(12) Patent Application Publication
(10) Pub. No.: US 2024/0397771 A1
(43) Pub. Date: Nov. 28, 2024

(54) DISPLAY APPARATUS, AND DISPLAY PANEL AND MANUFACTURING METHOD THEREFOR

(71) Applicant: BOE Technology Group Co., Ltd., Beijing (CN)

(72) Inventors: Xueyan TIAN, Beijing (CN); Yibing FAN, Beijing (CN); Xuliang ZHAO, Beijing (CN); Jianchao ZHU, Beijing (CN); Hao GAO, Beijing (CN); Shiming SHI, Beijing (CN)

(21) Appl. No.: 18/694,301

(22) PCT Filed: Nov. 30, 2021
(86) PCT No.: PCT/CN2021/134616

§ 371 Date: Mar. 21, 2024

(51) Int. Cl. H10K 59/131; H10K 59/12; H10K 59/122

(52) U.S. Cl. CPC H10K 59/131; H10K 59/1201; H10K 59/122

(57) ABSTRACT

A display panel includes: a substrate; a driving layer, arranged on one side of the substrate and including multiple circuit units distributed in an array, multiple row wiring harnesses, and multiple column wiring harnesses; where the circuit unit includes multiple pixel circuits; the row wiring harness includes multiple row wirings distributed at intervals along a column direction, the column wiring harness includes multiple column wirings distributed at intervals along a row direction; orthographic projections of the row wiring harnesses and the column wiring harnesses on the substrate cross and separate multiple transparent regions, and a region of the driving layer corresponding to the transparent region is a transparent structure; and a light emitting layer, arranged on a surface of the driving layer away from the substrate, and including multiple device units distributed in an array; where the device units correspond to the transparent regions.

### TECHNICAL FIELD

This disclosure relates to the field of display technology, and in particular, to a display device, a display panel, and a method for manufacturing the display panel.

### BACKGROUND

Organic electroluminescent display devices have been widely used due to their advantages such as low driving voltage, high luminous efficiency, short response time, and high contrast. Double-sided display devices are one of the hotspots in research and development. At present, double-sided display are usually implemented by pasting two display panels, which however increases the thickness and weight of the display device.

It is to be noted that the above information disclosed in this background section is only for enhancing understanding the context of the disclosure and, therefore, may contain information that does not form the prior art that is already known to those skilled in the art.

### SUMMARY

The disclosure provides a display device, a display panel and a method for manufacturing the display panel.

According to an aspect of this disclosure, there is provided a display panel, including:
a substrate;
a driving layer, arranged on one side of the substrate and including multiple circuit units distributed in an array, multiple row wiring harnesses, and multiple column wiring harnesses; where the circuit unit includes multiple pixel circuits; the row wiring harness includes multiple row wirings distributed at intervals along a column direction, the column wiring harness includes multiple column wirings distributed at intervals along a row direction; the circuit units in a same row are connected through one of the row wiring harnesses, and the circuit units in a same column are connected through one of the column wiring harnesses; orthographic projections of the row wiring harnesses and the column wiring harnesses on the substrate cross and separate multiple transparent regions, and a region of the driving layer corresponding to the transparent region is a transparent structure; and
a light emitting layer, arranged on a surface of the driving layer away from the substrate, and including multiple device units distributed in an array; where the device units correspond to the transparent regions; the device unit includes multiple light emitting devices distributed at intervals, each of the light emitting devices is connected to one of the pixel circuits; the light emitting device includes a first electrode, a light emitting functional layer and a second electrode stacked sequentially in a direction away from the substrate, and the first electrode and the second electrode are transparent structures.

In some exemplary embodiments of this disclosure, the light emitting layer further includes a pixel definition layer separating respective ones of the light emitting devices, and the pixel definition layer has openings defining the respective ones of the light emitting devices;
a region of the row wiring harness located between adjacent two of the circuit units is recessed radially to form a row recess, an orthographic projection of the row recess on the substrate is at least a part of the transparent region, and an orthographic projection of one of the openings on the substrate at most partially coincides with the orthographic projection of the row recess on the substrate.

In some exemplary embodiments of this disclosure, the light emitting layer further includes a pixel definition layer separating respective ones of the light emitting devices, and the pixel definition layer has openings defining the respective ones of the light emitting devices;
a region of the column wiring harness located between adjacent two of the circuit units is recessed radially to form a column recess, an orthographic projection of the column recess on the substrate is at least a part of the transparent region, and an orthographic projection of one of the openings on the substrate at most partially coincides with the orthographic projection of the column recess on the substrate.

In some exemplary embodiments of this disclosure, the light emitting layer further includes a pixel definition layer separating respective ones of the light emitting devices, and the pixel definition layer has openings defining the respective ones of the light emitting devices;
a region of the row wiring harness located between adjacent two of the circuit units is recessed radially to form a row recess, an orthographic projection of the row recess on the substrate is at least a part of the transparent region, and an orthographic projection of one of the openings on the substrate at most partially coincides with the orthographic projection of the row recess on the substrate; and
a region of the column wiring harness located between adjacent two of the circuit units is recessed radially to form a column recess, an orthographic projection of the column recess on the substrate is at least a part of the transparent region, and an orthographic projection of one of the openings on the substrate at most partially coincides with the orthographic projection of the column recess on the substrate.

In some exemplary embodiments of this disclosure, one of the device units includes three light emitting devices with different light emitting colors, and the first electrodes of the three light emitting devices have different sizes.

In some exemplary embodiments of this disclosure, the one of the device units includes a first light emitting device emitting green light, a second light emitting device emitting red light, and a third light emitting device emitting blue light;
an area of the first electrode of the third light emitting device is larger than an area of the first electrode of the first light emitting device, and the area of the first electrode of the first light emitting device is larger than an area of the first electrode of the second light emitting device.

In some exemplary embodiments of this disclosure, an orthographic projection of the opening corresponding to the first light emitting device on the substrate at most partially coincides with the orthographic projection of the column recess on the substrate;
an orthographic projection of the opening corresponding to the second light emitting device on the substrate at most partially coincides with the orthographic projection of the row recess on the substrate;
an orthographic projection of the opening corresponding to the third light emitting device on the substrate at most partially coincides with the orthographic projection of the row recess on the substrate, and at most partially coincides with the orthographic projection of the column recess on the substrate.

In some exemplary embodiments of this disclosure, among the first electrodes of the device unit corresponding to one of the transparent regions, an orthographic projection of at least one of the first electrodes on the substrate partially coincides with an orthographic projection of one of the row wiring harnesses on the substrate; and an orthographic projection of at least one of the first electrodes on the substrate partially coincides with an orthographic projection of one of the column wiring harnesses on the substrate.

In some exemplary embodiments of this disclosure, in orthographic projections of one of the transparent regions and a corresponding one of the device units on the substrate:
the one of the transparent regions includes a first sub-region and a second sub-region, the first sub-region extends along a first direction different from the row direction and the column direction; the second sub-region is located on one side of the first sub-region, and extends, along a second direction intersecting with the first direction, to adjoin the first sub-region, where the second direction is different from the row direction and the column direction;
orthographic projections of the first electrode of the first light emitting device and the first electrode of the second light emitting device on the driving layer are located on a same side of the first sub-region, and are distributed along the first direction on two sides of the second sub-region; and an orthographic projection of the first electrode of the third light emitting device on the driving layer is located on one side of the first sub-region away from the second sub-region.

In some exemplary embodiments of this disclosure, the row wiring harness includes multiple row wirings, and the row wirings include scanning lines;
the column wiring harness includes multiple column wirings, and the column wirings include data lines.

In some exemplary embodiments of this disclosure, pixel circuits connected to different light emitting devices of a same one of the device units are located in different ones of the circuit units.

In some exemplary embodiments of this disclosure, the pixel circuits connected to different light emitting devices of a same one of the device units are located in a same row of the circuit units.

In some exemplary embodiments of this disclosure, the first electrode of each light emitting device of any one of the device units is connected to one of the pixel circuits through a connection part;
the first electrode of a first light emitting device is connected to one of the pixel circuits through a first connection part; the first electrode of a second light emitting device is connected to one of the pixel circuits through a second connection part, and the first electrode of a third light emitting device is connected to one of the pixel circuits through a third connection part;
pixel circuits connected to the first connection part and the second connection part are located in a same one of the circuit units, which is different from, but in a same row as, one of the circuit units where the one of the pixel circuits connected to the third connection part is located in; and
a length of the first connection part in its extending direction is less than a length of the second connection part in its extending direction, and the length of the second connection part in its extending direction is less than a length of the third connection part in its extending direction.

In some exemplary embodiments of this disclosure, the driving layer includes: an active layer, provided on one side of the substrate;
a first gate insulating layer, covering the active layer and the substrate;
a gate, provided on a surface of the first gate insulating layer away from the substrate;
a second gate insulating layer, covering the gate and the first gate insulating layer;
an interlayer dielectric layer, covering the second gate insulating layer;
a source-drain layer, provided on a surface of the interlayer dielectric layer away from the substrate; and
a planarization layer, covering the source-drain layer and the interlayer dielectric layer;
where the display panel further includes:
an encapsulation layer, covering the light emitting layer; and
a touch layer, provided on a surface of the encapsulation layer away from the substrate.

In some exemplary embodiments of this disclosure, the first electrode includes a first transparent conductive layer, a conductive metal layer and a second transparent conductive layer sequentially stacked in the direction away from the substrate, a resistivity of the conductive metal layer is less than resistivities of the first transparent conductive layer and the second transparent conductive layer; and
a thickness of the conductive metal layer is not less than 200 Å and not greater than 300 Å.

In some exemplary embodiments of this disclosure, thicknesses of the first transparent conductive layer and the second transparent conductive layer are not less than 80 Å and not greater than 100 Å.

In some exemplary embodiments of this disclosure, a thickness of the second electrode is not less than 13 nm and not greater than 15 nm.

According to an aspect of this disclosure, there is provided a method for manufacturing a display panel, including:
forming a driving layer on one side of a substrate, where the driving layer includes multiple circuit units distributed in an array, multiple row wiring harnesses, and multiple column wiring harnesses; the circuit unit includes multiple pixel circuits; the row wiring harness includes multiple row wirings distributed at intervals along a column direction, the column wiring harness includes multiple column wirings distributed at intervals along a row direction; the circuit units in a same row are connected through one of the row wiring harnesses, and the circuit units in a same column are connected through one of the column wiring harnesses; orthographic projections of the row wiring harnesses and the column wiring harnesses on the substrate cross and separate multiple transparent regions, and a region of the driving layer corresponding to the transparent region is a transparent structure; and
forming a light emitting layer, on a surface of the driving layer away from the substrate, including multiple device units distributed in an array, where the device units correspond to the transparent regions; the device unit includes multiple light emitting devices distributed at intervals, each of the light emitting devices is connected to one of the pixel circuits; the light emitting device includes a first electrode, a light emitting functional layer and a second electrode stacked sequentially in a direction away from the substrate, and the first electrode and the second electrode are transparent structures.

According to an aspect of this disclosure, a display device is provided, including the display panel according to any embodiment described above.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of this disclosure, and those skilled in the art can obtain other drawings according to these drawings without creative efforts.

FIG. 1 is a cross-sectional view of a display panel according to some embodiments of this disclosure.

FIG. 2 is a schematic diagram of a pixel circuit in the display panel according to some embodiments of this disclosure.

FIG. 3 is a layout diagram of a pixel circuit in the display panel according to some embodiments of this disclosure.

FIG. 4 is a layout diagram of a pixel circuit and a first electrode in the display panel according to some embodiments of this disclosure.

FIG. 5 to FIG. 8 are partial top views of a part of film layers of a pixel circuit in the display panel according to some embodiments of this disclosure, respectively.

FIG. 9 is a partial schematic diagram of a driving layer in the display panel according to some embodiments of this disclosure.

FIG. 10 is a partial schematic diagram of a driving layer and an opening in the display panel according to some embodiments of this disclosure.

FIG. 11 is a partial schematic diagram of a driving layer, an opening and a first electrode in the display panel according to some embodiments of this disclosure.

FIG. 12 is a partial schematic diagram of the connection between the first electrode and the pixel circuit in the display panel according to some embodiments of this disclosure.

FIG. 13 is a partial schematic diagram of a driving layer, an opening, a first electrode and a second electrode in the display panel according to some embodiments of this disclosure.

FIG. 14 to FIG. 17 are partial top views of some film layers in the display panel according to some embodiments of this disclosure.

FIG. 18 is a test result diagram of the thickness of the first electrode and the light transmittance of the display panel according to some embodiments of this disclosure.

### DETAILED DESCRIPTION

Exemplary embodiments will now be described more fully with reference to the accompanying drawings. Exemplary embodiments may, however, be embodied in many forms and should not be construed as limited to the embodiments set forth herein. Rather, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted. Furthermore, the drawings are merely schematic illustrations of this disclosure and are not necessarily drawn to scale.

The terms “a”, “an”, “the”, “said” and “at least one” are used to indicate the presence of one or more elements/components/etc.; the terms “comprise/include” and “have” are used to indicate an open inclusion and means that there may be additional elements/components/etc. in addition to the listed elements/components/etc.; the terms “first”, “second” and “third” etc. are only used as a marker, not a limit on the number of its object.

A transistor refers to an element including at least three terminals: a gate electrode, a drain electrode, and a source electrode. A transistor has a channel region between the drain electrode (drain electrode terminal, drain region, or drain electrode) and the source electrode (source electrode terminal, source region, or source electrode), and current can flow through the drain electrode, the channel region, and the source electrode. The channel region refers to a region through which current mainly flows.

The first terminal may be the drain electrode and the second terminal may be the source electrode; or the first terminal may be the source electrode and the second terminal may be the drain electrode. In cases where transistors with opposite polarities are used or when the direction of current changes during circuit operation, the functions of the “source electrode” and “drain electrode” may be interchanged. Therefore, in this specification, “source electrode” and “drain electrode” can be interchanged with each other.

The row direction and column direction herein refer to two mutually intersecting directions. For example, the row direction may be the horizontal direction in the drawing, and the column direction may be the longitudinal direction in the drawing, and the two are perpendicular to each other. However, this should not be regarded as a limitation on the row direction and the column direction. The row direction does not necessarily refer to the horizontal direction, and the column direction does not necessarily refer to the vertical direction. Those skilled in the art can know that if the position of the display panel changes such as rotates, the actual orientation of the row direction and the column direction may change.

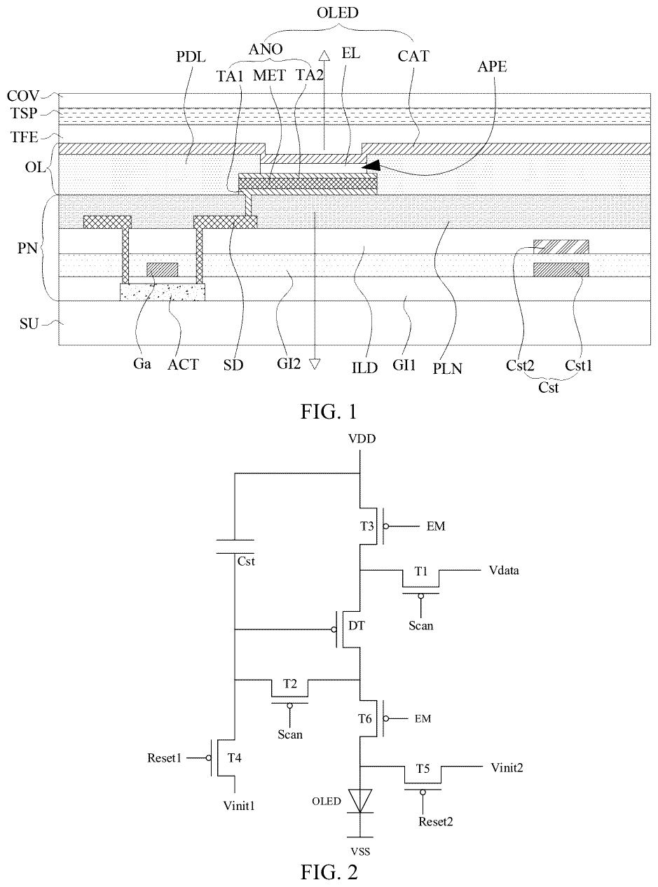

Some embodiments of this disclosure provide a display panel. As shown in FIG. 1, the display panel may include a substrate SU, a driving layer PN, and a light emitting layer OL.

The driving layer PN is arranged on one side of the substrate SU and includes multiple circuit units CU distributed in an array, multiple row wiring harnesses LR, and multiple column wiring harnesses LC. The circuit unit CU includes multiple pixel circuits PC; the row wiring harness LR includes multiple row wirings distributed at intervals along the column direction Y, the column wiring harness LC includes multiple column wirings distributed at intervals along the row direction X. The circuit units CU in a same row are connected through one of the row wiring harnesses LR, and the circuit units CU in a same column are connected through one of the column wiring harnesses LC. Orthographic projections of the row wiring harnesses LR and the column wiring harnesses LC on the substrate SU cross and separate multiple transparent regions TRA, and a region of the driving layer PN corresponding to the transparent region TRA is a transparent structure.

The light emitting layer OL is arranged on a surface of the driving layer PN away from the substrate SU, and includes multiple device units DC distributed in an array. The device units DC correspond to the transparent regions TRA. The device unit DC includes multiple light emitting devices OLED distributed at intervals, each of the light emitting devices OLED is connected to one of the pixel circuits PC. The light emitting device OLED includes a first electrode ANO, a light emitting functional layer EL and a second electrode CAT stacked sequentially in a direction away from the substrate SU, and the first electrode ANO and the second electrode CAT are transparent structures.

In the display panel according to some embodiments of this disclosure, both the first electrode ANO and the second electrode CAT of the light emitting device OLED may be provided as transparent structures, so that the light emitting device OLED can emit light in two directions, thereby realizing double-sided display. Herein, the light emitting device OLED emits light in a direction away from the substrate SU for front display, and the light emitting device OLED emits light in a direction close to the substrate SU for rear display.

Also, since both the first electrode ANO and the second electrode CAT are in transparent structures, and a region of the driving layer PN corresponding to the transparent region TRA is in a transparent structure, the display panel has a transparent effect.

In addition, the pixel circuits PC and the light emitting devices OLED may be distributed according to the circuit units CU and the device units DC, and the device units DC are provided corresponding to the transparent region TRA, thereby alleviating or avoiding blocking of the light emitting device OLED by the pixel circuit PC, the row wiring harness LR and the column wiring harness LC, so as to increase the brightness of the backlight and reduce the brightness difference with the front light, as well as improve the transparency effect.

The basic structure of the display panel according to some embodiments of this disclosure will be described in detail below.

The display panel can be used for bidirectional light emission, that is, front display and back display, and can realize transparent display. The display panel may include a substrate SU, a driving layer PN and a light emitting layer OL.

As shown in FIG. 1, the substrate SU may be a flat plate serving as a bearing, and its shape may be rectangular or other shapes. The material of the substrate SU may include transparent hard materials such as glass, or flexible materials such as polyimide (PI). The substrate SU may be a single-layer or multi-layer structure, which is not specifically limited here.

As shown in FIG. 1, the driving layer PN may be directly stacked on one side of the substrate SU. Alternatively, in order to avoid the influence of impurities in the substrate SU on the driving layer PN, a buffer may also be provided between the substrate SU and the driving layer PN, and the driving layer PN may be disposed on a surface of the buffer layer away from the substrate SU. The driving layer PN, the substrate SU and the film layers between them may form a driving backplane. The driving layer PN includes at least a driving region and a peripheral region. The peripheral region may be an annular region surrounding the driving region, or two discontinuous regions separated on both sides of the driving region, as long as it is located outside the driving region.

The driving layer PN is provided a driving circuit for driving the light emitting device OLED of the light emitting layer OL to emit light. The driving circuit may include multiple pixel circuits PC and peripheral circuits. The pixel circuits PC are provided in the driving region. Also, partial region of a part of the pixel circuits PC may be located in the peripheral region. The number of pixel circuits PC may be the same as that of the light emitting devices OLED, and they are connected to respective light emitting device OLED in a one-to-one correspondence, so as to control each light emitting device OLED to emit light independently. Also, a single pixel circuit PC may also be connected to multiple light emitting devices OLED, so as to drive multiple light emitting devices OLED to emit light. The peripheral circuit is located in the peripheral region and is connected to the pixel circuits PC for inputting a driving signal to the pixel circuits PC, so as to control the light emitting device OLED to emit light. The peripheral circuit may include a light emission control circuit, a gate driving circuit, a source driving circuit, a power supply circuit, and the like.

The pixel circuit PC may have a structure such as 7T1C, 7T2C, 6T1C or 6T2C, as long as it may drive the light emitting device OLED to emit light, which is not particularly limited here. Herein, nTmC indicates that a pixel circuit PC includes n transistors (indicated by the letter “T”) and m capacitors (indicated by the letter “C”). Also, one pixel circuit PC may also be connected to multiple light emitting devices OLED at the same time, and may drive the multiple light emitting devices OLED to emit light at the same time or in time division manner.

Taking a pixel circuit PC with the 7T1C structure as an example, the structure and driving method of the pixel circuit PC are exemplarily described below.

As shown in FIG. 2, the pixel circuit PC may include seven transistors and one storage capacitor, that is, a driving transistor DT, the first transistor T1 to the sixth transistor T6 and a storage capacitor Cst.

The control terminal of the first transistor T1 may be configured to receive the writing control signal Scan, the first terminal thereof is configured to receive the data signal Vdata, and the second terminal thereof is connected to the first end of the driving transistor DT.

The control terminal of the second transistor T2 is configured to receive the write control signal Scan, the first terminal thereof is connected to the second terminal of the driving transistor DT, and the second terminal thereof is connected to the control terminal of the driving transistor DT.

The control terminal of the third transistor T3 is configured to receive the light emission control signal EM, the first terminal thereof is configured to receive the first power supply signal VDD, and the second terminal thereof is connected to the first terminal of the driving transistor DT.

The control terminal of the fourth transistor T4 is configured to receive the first reset control signal Reset1, the first terminal thereof is configured to receive the first reset signal Vinit1, and the second terminal thereof is connected to the control terminal of the driving transistor DT.

The control terminal of the fifth transistor T5 is configured to receive the second reset control signal Reset2, the first terminal thereof is configured to receive the second reset signal Vinit2, and the second terminal thereof is connected to the first terminal of the light emitting device OLED.

The control terminal of the sixth transistor T6 is configured to receive the light emission control signal EM, the first terminal thereof is connected to the second terminal of the driving transistor DT, the second terminal thereof is connected to the first terminal of the light emitting device OLED, and the second terminal of the light emitting device OLED is configured to receive the second power signal VSS.

The first plate of the storage capacitor Cst is connected to the first terminal of the third transistor T3 for inputting the first power supply signal VDD, and the second plate thereof is connected to the control terminal of the driving transistor DT.

The above-mentioned driving transistor DT, first transistor T1 to sixth transistor T6 are all P-type thin film transistors. The first power supply signal VDD is a high-level signal, and the second power supply signal VSS is a low-level signal. The light emitting device OLED is an organic light emitting diode, with the first terminal thereof being the anode of the organic light emitting diode, and the second terminal thereof being the cathode of the organic light emitting diode. The driving transistor DT, the first transistor T1 to the sixth transistor T6 are all turned on when the level is low, and turned off when the level is high.

The above-mentioned driving method of the pixel circuit PC may include following content.

In the reset phase, the first reset signal Reset1 is transmitted to the control terminal of the fourth transistor T4, and the second reset signal Reset2 is transmitted to the control terminal of the fifth transistor T5, so as to turn on the fourth transistor T4 and the fifth transistor T5. At the same time, the first transistor T1, the second transistor T2, the third transistor T3 and the sixth transistor T6 are turned off, the first reset signal Vinit1 is transmitted to the control terminal of the driving transistor DT through the fourth transistor T4, and the second reset signal Vinit2 is transmitted to the first terminal of the light emitting device OLED through the fifth transistor T5. The first reset signal Vinit1 and the second reset signal Vinit2 may be signals having the same voltage.

In the data writing phase, the first transistor T1 and the second transistor T2 are turned on, and the third transistor T3, the fourth transistor T4, the fifth transistor T5 and the sixth transistor T6 are turned off, so as to transmit the data signal Vdata to the control terminal of the driving transistor DT through the first transistor T1, the driving transistor DT and the second transistor T2.

In the light emitting phase, the light emission control signal EM is transmitted to the control terminals of the third transistor T3 and the sixth transistor T6, so as to turn on the third transistor T3 and the sixth transistor T6. At the same time, the first transistor T1, the second transistor T2, the fourth transistors T4 and the fifth transistor T5 are turned off, so as to transmit the signal from the second terminal of the driving transistor DT to the first terminal of the light emitting device OLED, thereby controlling the light emitting device OLED to emit light.

The above-mentioned thin film transistors in the driving circuit layer may be top-gate or bottom-gate thin film transistors, and each thin film transistor may include an active layer ACT, a gate Ga, a source and a drain, where the gate Ga may be a double gate, and may also be a single gate or other structures. The active layers ACT of respective thin film transistors may be arranged on the same layer, the gates Ga may be arranged on the same layer, and the sources and drains may be arranged on the same layer, so as to simplify the process.

Taking a top-gate thin film transistor in the pixel circuit PC as an example, the structure of the driving layer PN is exemplarily described below.

As shown in FIG. 1, the driving layer PN may include an active layer ACT, a first gate insulating layer GI1, a gate Ga, a second gate insulating layer GI2, an interlayer dielectric layer ILD, a source-drain layer SD, and a planarization layer PLN.

The active layer ACT is arranged on one side of the substrate SU, and the first gate insulating layer GI1 covers the active layer ACT and the substrate SU. The gate Ga is arranged on a surface of the first gate insulating layer GI1 away from the substrate SU, and is arranged opposite to the active layer ACT. The second gate insulating layer GI2 covers the gate Ga and the first gate insulating layer GI1. The interlayer dielectric layer ILD covers the second gate insulating layer GI2. The source-drain layer SD is arranged on a surface of the interlayer dielectric layer ILD away from the substrate SU, and includes the source and the drain, where the source and the drain are connected to both ends of the active layer ACT through contact holes. The planarization layer PLN covers the source-drain layer SD and the interlayer dielectric layer ILD. Also, the driving circuit layer may further include other film layers, as long as it can drive the light emitting device OLED to emit light, which will not be described in detail here.

In addition, the driving layer PN may also include a first plate Cst1 and a second plate Cst2 of the storage capacitor Cst, where the first plate Cst1 may be provided on the same layer as the gate Ga, and the second plate Cst2 may be provided on a surface of the second gate insulation layer GI2 away from the substrate SU, and is arranged opposite to the first plate Cst1. The interlayer dielectric layer ILD covers the second polar plate Cst2.

The layout of the 7T1C pixel circuit PC in FIG. 2 is exemplarily described below in conjunction with FIG. 3 to FIG. 8.

As shown in FIG. 3 to FIG. 8, the driving layer PN may include a semiconductor layer 001, a first conductive layer 002, a second conductive layer 003, and a third conductive layer 004.

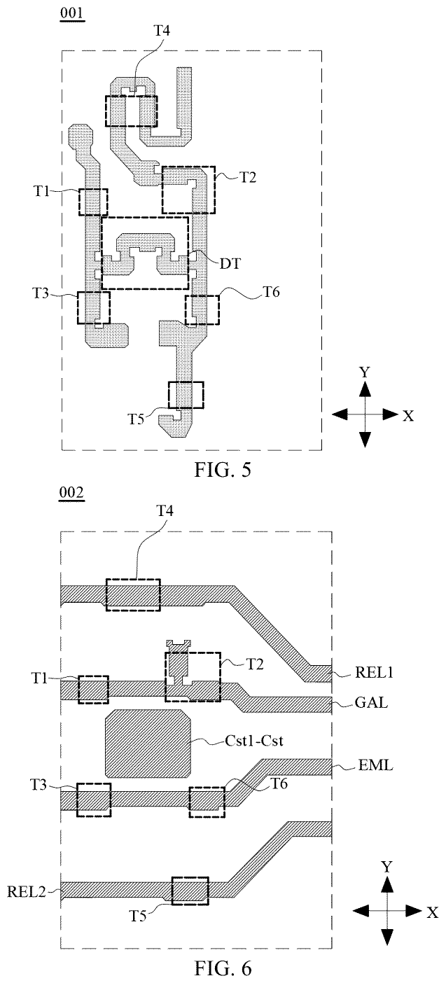

As shown in FIG. 3 and FIG. 5, the semiconductor layer 001 includes active layers ACT of respective transistors (driving transistor DT, first transistor T1 to sixth transistor T6).

As shown in FIG. 3 and FIG. 6, the first conductive layer 002 includes the gate of each transistor, the scanning line GAL, the light emission control line EML, the first reset line REL1, the second reset line REL2 and the first plate of the storage capacitor Cst, which may be located on the first conductive layer 002.

The scanning line GAL extends along the row direction X and overlaps the active layer ACT of the first transistor T1 and the second transistor T2, and the overlapping region includes the gates of the first transistor T1 and the second transistor T2. The writing control signal Scan may be input to the first transistor T1 and the second transistor T2 through the scanning line GAL.

The light emission control line EML may extend along the row direction X and overlap the active layer ACT of the third transistor T3 and the sixth transistor T6, and the overlapping region includes the gates of the third transistor T3 and the sixth transistor T6. The light emission control signal EM may be input to the third transistor T3 and the sixth transistor T6 through the light emission control line EML.

The first reset line REL1 may extend along the row direction X and overlap the active layer ACT of the fourth transistor T4, and the overlapping region is the gate of the fourth transistor T4. The first reset control signal Reset1 may be input to the fourth transistor T4 through the first reset line REL1, so as to turn on the fourth transistor T4.

The second reset line REL2 may extend along the row direction X and overlap with the active layer ACT of the fifth transistor T5, and the overlapping region is the gate of the fifth transistor T5. The second reset control signal Reset2 may be input to the fifth transistor T5 through the second reset line Rel2, so as to turn on the fifth transistor T5. The first reset control signal Reset1 and the second reset control signal Reset2 may be transmitted simultaneously or not.

The first plate Cst1 of the storage capacitor Cst may also be used as the gate of the driving transistor DT, so as to connect the first plate Cst1 to the gate of the driving transistor DT.

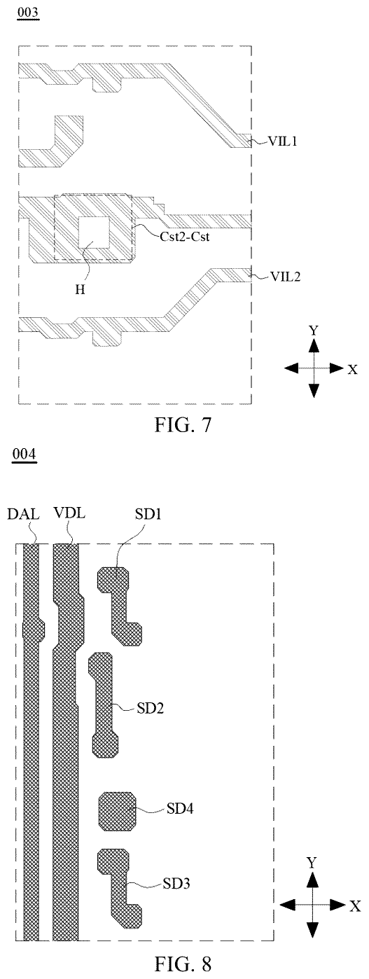

As shown in FIG. 3 and FIG. 7, the second conductive layer 003 may include a first reset signal line VIL1, a second reset signal line VIL2 and a second plate Cst2 of the storage capacitor Cst.

The first reset signal line VIL1 and the second reset signal line VIL2 may extend along the row direction X, the first reset signal line VIL1 is configured to transmit the first reset signal Vinit1 to the fourth transistor T4, and the second reset signal line VIL2 is configured to transmit the second reset signal Vinit2 to the fifth transistor T5.

The second plate Cst2 is arranged opposite to the first plate Cst1, that is, the orthographic projections of the two plates on the substrate SU at least partially overlap each other, so as to form the storage capacitor Cst.

As shown in FIG. 3 and FIG. 8, the third conductive layer 004 may include a data line DAL, a power supply line VDL, as well as a first conductive portion SD1, a second conductive portion SD2, a third conductive portion SD3, and a fourth conductive portion SD4 distributed at intervals.

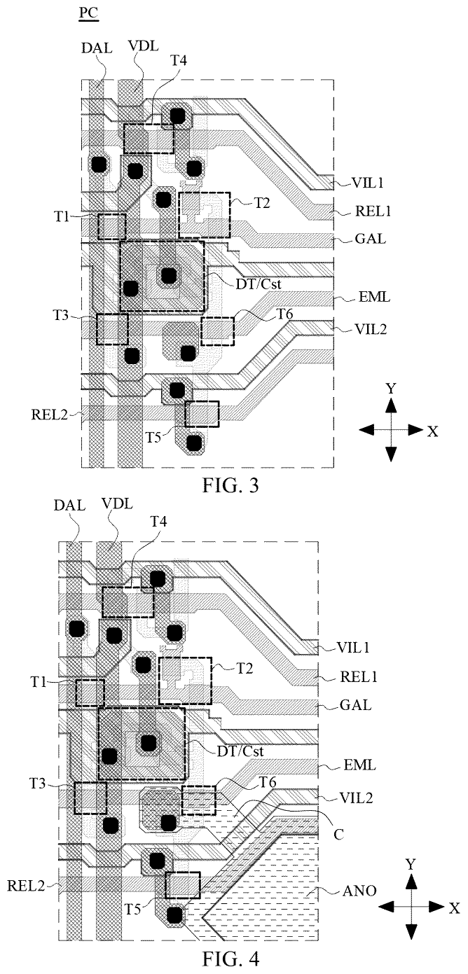

The first conductive portion SD1 may be connected to the first reset signal line VIL1 and the fourth transistor T4; the second conductive portion SD2 may be connected to the fourth transistor T4, the driving transistor DT and the storage capacitor Cst; the third conductive portion SD3 may be connected to the second reset signal line VIL2 and the fifth transistor T5; and the fourth conductive portion SD4 may be connected to the sixth transistor T6 for connecting with the first electrode ANO of a light emitting device OLED, as shown in FIG. 4.

As shown in FIG. 3 and FIG. 7, in order to ensure that the second transistor T2 and the fourth transistor T4 can be connected with the first plate Cst1 of the storage capacitor Cst and the gate of the driving transistor DT, a through hole H may be opened on the second plate Cst2. The second transistor T2 and the fourth transistor T4 are connected to the first plate Cst1 and the gate of the driving transistor DT by means of the second conductive portion S2 passing through the contact hole of the through hole H.

The data line DAL and the power supply line VDL may extend along the column direction Y and may be distributed along the row direction X at intervals, where the data line DAL may be connected to the first transistor T1, and the power supply line VDL may be connected to the third transistor T3 and the second plate Cst2 and configured to transmit the first power supply signal VDD.

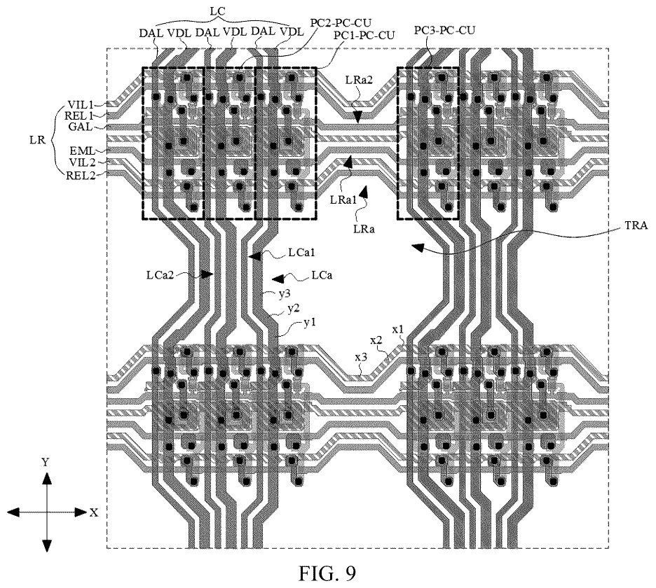

As shown in FIG. 9, for the entire driving layer PN, the pixel circuits PC are distributed in an array, the pixel circuits PC in the same row may share the first reset signal line VIL1, the second reset signal line VIL2, the light emission control line EML and the scanning line GAL extending along the row direction X, and the pixel circuits PC in the same column may share the data line DAL and the power supply line VDL. Also, there may be wiring sharing between different rows and different columns.

As shown in FIG. 1, the light emitting layer OL is disposed on one side of the driving layer PN, for example, the light emitting layer OL is disposed on a surface of the planarization layer PLN away from the substrate SU. The light emitting layer OL may include multiple light emitting devices OLED distributed in an array, and each light emitting device OLED may emit light under the driving of the pixel circuit PC.

In some embodiments of this disclosure, the light emitting device OLED is an organic light emitting diode, which may include a first electrode ANO, a light emitting functional layer EL, and a second electrode CAT sequentially stacked in a direction away from the substrate SU.

The first electrode ANO may be arranged on a surface of the planarization layer PLN away from the substrate SU, and may be connected to one of the pixel circuits PC through a contact hole. For example, as shown in FIG. 2 and FIG. 4, the first electrode ANO may be connected to the sixth transistor T6.

As shown in FIG. 4, in some embodiments of this disclosure, the first electrode ANO may be connected to the pixel circuit PC through a connection part C, where the connection part C and the first electrode ANO are integrally structured, and the connection part C may extend outward, from an edge of the first electrode ANO, along a track such as a straight line, a curve, or a broken line, as long as it can extend above the pixel circuit PC and can be connected to the pixel circuit PC through a contact hole. For example, one end of the connection part C is connected to the first electrode ANO, and the other end is connected to the sixth transistor T6 through a contact hole.

The first electrode ANO may be a single-layer or multi-layer structure, and it may be used as the anode of the light emitting device OLED. For example, as shown in FIG. 1, the first electrode ANO may include a first transparent conductive layer TA1, a conductive metal layer MET, and a second transparent conductive layer TA2 sequentially stacked in a direction away from the substrate SU. The conductive metal layer MET may have its resistivity less than those of the first transparent conductive layer TA1 and the second transparent conductive layer TA2. For example, the material of the first transparent conductive layer TA1 and the second transparent conductive layer TA2 may be a transparent conductive material such as indium tin oxide (ITO), and the material of the conductive metal layer MET may be silver (Ag).

As shown in FIG. 1, the light emitting functional layer EL is arranged on a surface of the first electrode ANO away from the substrate SU, and may include a hole injection layer, a hole transport layer, a composite light emitting layer OL, an electron transport layer and an electron injection layer stacked sequentially along the direction away from the substrate SU. In addition, an electron blocking layer may further be provided between the hole transport layer and the composite light emitting layer OL.

As shown in FIG. 1, the second electrode CAT covers the light emitting functional layer EL and may extend to the peripheral region. The second electrode CAT may be connected to a power supply signal terminal to receive the second power supply signal VSS. The first electrode ANO and the second electrode CAT may work together to make the light emitting device OLED emit light, and the specific light emitting principle of the organic light emitting diode will not be described in detail here. The material of the second electrode CAT may be magnesium (Mg), silver alloy, or other materials.

As shown in FIG. 1, in order to define the range of each light emitting device OLED, the light emitting layer OL may further include a pixel definition layer PDL, which may be arranged with the first electrode ANO on the surface of the driving layer PN away from the substrate SU, and is provided with multiple openings APE exposing respective first electrodes ANO in one-to-one correspondence. The shape of the opening APE may be a polygon such as a quadrangle, a pentagon, a hexagon, or a figure such as a circle or an ellipse, which is not particularly limited here. The light emitting functional layer EL is stacked on a region of the first electrode ANO located in the opening APE. The light emitting functional layers EL of respective light emitting devices OLED are distributed at intervals independently of each other. The luminescent colors of different light emitting functional layers EL may be the same or different. The second electrode CAT covers each light emitting functional layer EL at the same time, so that each light emitting device OLED may share the same second electrode CAT. Respective light emitting devices OLED can be defined by the above-mentioned multiple openings APE, and the boundary of any light emitting device OLED is the boundary of its corresponding opening APE.

As shown in FIG. 4, the pixel definition layer PDL may cover the connection part C, so that the light emitting functional layer EL is not stacked with the connection part C, so that the connection part C does not emit light, thereby avoiding a problem that, when the first electrode ANO is directly connected to the pixel circuit PC without using the connection part C, light cannot be emitted at the position of the contact hole and, accordingly, the light emitting area is reduced.

Respective light emitting devices OLED may include multiple light emitting devices OLEDs with different light emitting colors, for example, a first light emitting device ROLED emitting red light, a second light emitting device GOLED emitting green light and a third light emitting device BOLED emitting blue light.

As shown in FIG. 1, in some embodiments of this disclosure, the display panel may further include an encapsulation layer TFE, which may cover a surface of the light emitting layer OL away from the substrate SU, and cover all the light emitting devices OLED, so as to protect the light emitting layer OL, and prevent the light emitting device OLED from being corroded by the external water and oxygen. At the same time, the boundary of the encapsulation layer TFE may extend into the peripheral region, but does not exceed the peripheral region, so as to protect the peripheral circuits in the peripheral region.

For example, the encapsulation may be realized by thin-film encapsulation (TFE). The encapsulation layer TFE may include a first inorganic layer, an organic layer and a second inorganic layer, where the first inorganic layer covers a surface of the light emitting layer OL away from the substrate SU, the organic layer may be arranged on a surface of the first inorganic layer away from the substrate SU and have its boundary being limited to the inner side of the boundary of the first inorganic layer, and the second inorganic layer covers the organic layer and the first inorganic layer that is not covered by the organic layer. Accordingly, the intrusion of water and oxygen can be blocked through the second inorganic layer, and planarization can be realized through a flexible organic layer.

As shown in FIG. 1, in some embodiments of this disclosure, the display panel may further include a touch layer TSP, which may be disposed on a surface of the encapsulation layer TFE away from the substrate SU. In other words, FMLOC (Flexible Multi-Layer On Cell) may be adopted for sensing touch operations. The touch layer TSP may adopt a self-capacitance or mutual-capacitance touch structure, the specific structure of which is not particularly limited here, as long as the touch function can be realized.

In addition, as shown in FIG. 1, in some embodiments of this disclosure, the display panel may further include a transparent cover COV, which may be provided on the surface of the touch layer TSP away from the substrate SU for protection. When the user performs touch operation, he/she may touch on the transparent cover COV. The transparent cover COV may be bonded to a surface of the touch layer TSP away from the substrate SU through optical glue or other adhesives. The transparent cover COV may be UTG (Ultra Thin Glass) or other transparent film layers, as long as it may play the role of protection and light transmission.

It should be noted that, in order to ensure the effect of transparent display, the touch layer TSP and the transparent cover COV in this disclosure are sequentially stacked on the encapsulation layer TFE without providing a circular polarizing layer.

The scheme for improving light transmittance will be described in detail below in combination with the above-mentioned embodiments.

As shown in FIG. 9 to FIG. 12, in order to improve the transmittance, the distribution of the pixel circuit PC and the light emitting device OLED may be adjusted. The pixel circuit PC may be divided into multiple circuit units CU, where each circuit unit CU may include multiple pixel circuits PC, each circuit unit CU may be arranged in an array along the row direction X and the column direction Y, and there is a certain distance between two adjacent circuit units CU. Also, the light emitting device OLED may be divided into multiple device units DC, where respective device units DC may be distributed in an array along the row direction X and the column direction Y, and there is a certain distance between two adjacent device units DC. In the same circuit unit CU, the pixel circuits PC may be distributed along the row direction X at intervals, and the distance between two adjacent circuit units CU is greater than the distance between two adjacent pixel circuits PC in the same circuit unit CU.

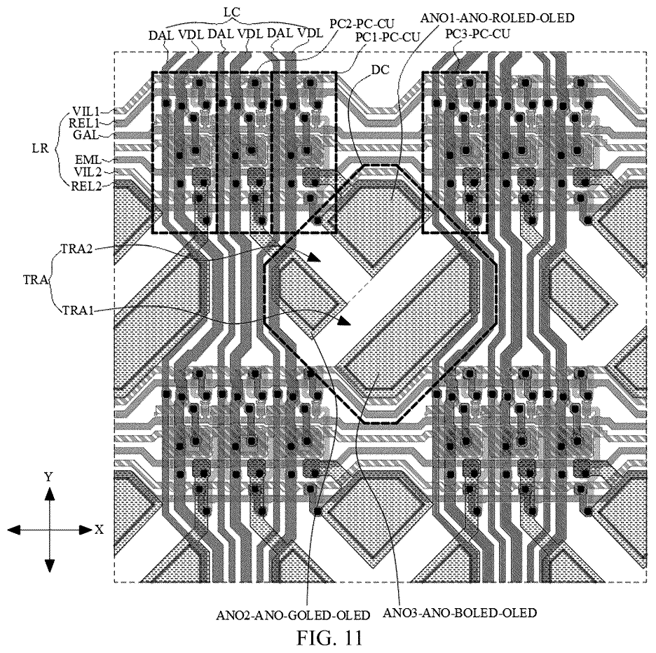

As shown in FIG. 11, each device unit DC may include multiple light emitting devices OLED. Each device unit DC is provided in a region outside a corresponding circuit unit CU, so as to alleviate the shading of the light emitting device OLED by the pixel circuit PC, thereby being beneficial to improve the rear display effect. In other words, the orthographic projection of the device unit DC on the substrate SU is at least partially located outside the orthographic projection of the circuit unit CU on the substrate SU.

As shown in FIG. 9 to FIG. 12, the orthographic projection of the row wiring harnesses LR on the substrate SU and the orthographic projection of the column wiring harnesses LC on the substrate SU intersect with each other and, together with the circuit unit CU, separate multiple transparent regions TRA. A region of the driving layer PN corresponding to the transparent region TRA is a transparent structure. In respective device units DC, one device unit DC is provided corresponding to one transparent region TRA, that is, the orthographic projection of one device unit DC on the driving backplane at least partially coincides with one transparent region TRA. In the direction perpendicular to the substrate SU, the device unit DC and the circuit unit CU may be staggered, and the device unit DC, the row wiring harness LR and the column wiring harness LC are also staggered, so as to reduce the shading of the light emitting device OLED by the pixel circuit PC, thereby being beneficial to improve the brightness of the rear display.

A region of the display panel corresponding to the transparent region TRA is not provided with any pixel circuit PC or wiring, which is equivalent to removing the conductive material that is easy to block light, so that the light transmittance of this region is relatively high. For example, a region of the driving layer PN corresponding to the transparent region TRA may include a first gate insulating layer GI1, a second gate insulating layer GI2, an interlayer dielectric layer ILD, a planarization layer PLN, a pixel definition layer PDL and the like which are stacked.

As shown in FIG. 9 to FIG. 12, based on the above concept, in detail, the driving layer PN may further include multiple row wiring harnesses LR and multiple column wiring harnesses LC.

The row wiring harnesses LR may extend along the row direction X and be distributed along the column direction Y at intervals, and one of the row wiring harnesses LR may include multiple row wirings distributed along the column direction Y at intervals.

The column wiring harnesses LC may extend along the column direction Y and be distributed along the row direction X at intervals, and one of the column wiring harnesses LC may include multiple column wirings distributed along the row direction X at intervals.

The circuit units CU in the same row may be connected through one of the row wiring harnesses LR, and the pixel circuits PC in the same row may be connected through multiple row wirings. The circuit units CU in the same column may be connected through one of the column wiring harnesses LC, and the pixel circuits PC in the same column may be connected through multiple columns wirings. For example, the row wirings of each row wiring harness LR may include scanning lines and the like; and the column wirings of each column wiring harness LC may include data lines and the like. Also, both the row wiring harness LR and the column wiring harness LC are connected to the peripheral circuit, so that the driving signal can be transmitted to the pixel circuit PC through the peripheral circuit, so as to drive the light emitting device OLED to emit light through the pixel circuit PC.

In some embodiments of this disclosure, as shown in FIG. 9 to FIG. 12, the row wirings of one row wiring harness LR may include the first reset signal line VIL1, the second reset signal line VIL2, the light emission control line EML, the scanning line GAL that are connected with the circuit units in the same row. The column wirings of one column wiring harness LC may include the data line DAL and the power supply line VDL that are connected with the circuit units CU in the same column.

In order to facilitate wiring, the pixel circuits PC connected to different light emitting devices OLED of the same device unit DC may be located in different circuit units CU. Further, the pixel circuits PC connected to different light emitting devices OLED of the same device unit DC may be located in the circuit units CU in the same row.

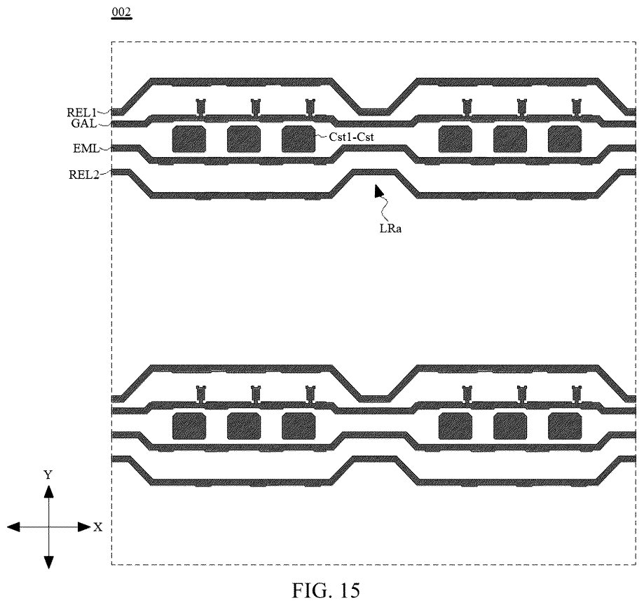

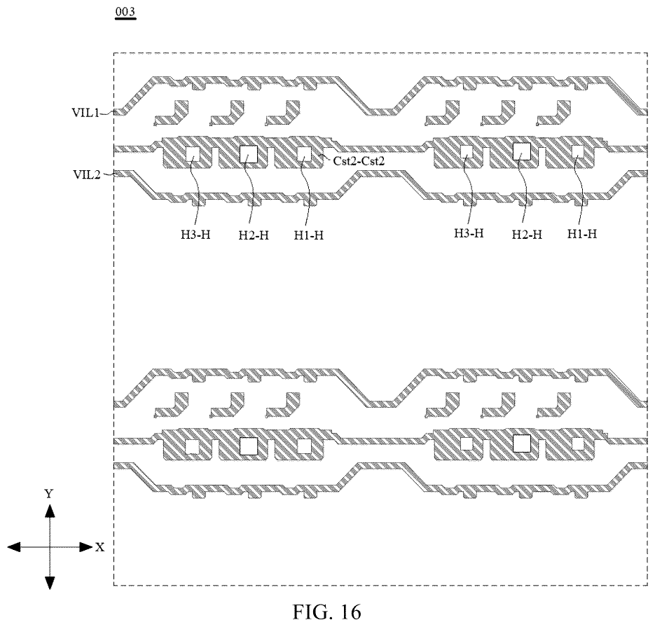

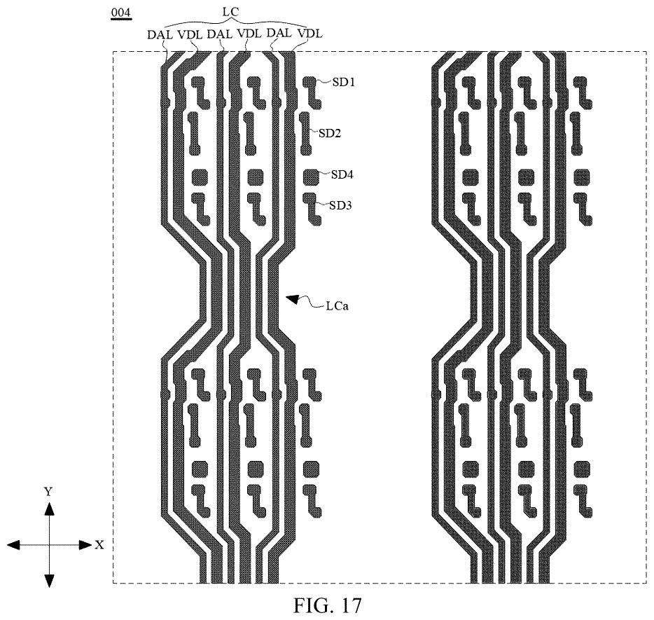

FIG. 14 to FIG. 17 show the schematic view of each film layer based on the above-mentioned FIG. 3 to FIG. 9, where FIG. 14 shows the pattern of the semiconductor layer 001, FIG. 15 shows the pattern of the first conductive layer 002, FIG. 16 shows the pattern of the second conductive layer 003, and FIG. 17 shows the pattern of the third conductive layer 004.

As shown in FIG. 4, FIGS. 11 and 16, in some embodiments of this disclosure, for the first pixel circuit PC1, the second pixel circuit PC2 and the third pixel circuit PC3 of a same circuit unit CU, in the third conductive layer 003, the second plate Cst2 of the first pixel circuit PC1 is provided with a through hole H1, the second plate Cst2 of the second pixel circuit PC2 is provided with a through hole H2, and the second plate Cst2 of the third pixel circuit PC3 is provided with a through hole H3. The first light emitting device ROLED connected to the first pixel circuit PC1 emits red light, the second light emitting device GOLED connected to the second pixel circuit PC2 emits green light, and the third light emitting device BOLED connected to the third pixel circuit PC3 emits blue light. Since the turn-on voltage of the second light emitting device GOLED is different from that of the first light emitting device ROLED and the third light emitting device BOLED, the storage capacitor Cst of the second pixel circuit PC2 may be different from the storage capacitors Cst connected to the first pixel circuit PC1 and the third pixel circuit PC3. For example, the storage capacitors Cst may be made different by making the facing areas between the first plate Cst1 and the second plate Cst2 different, for example, the size of the through hole H2 may be different from that of the through holes H1 and H3, so as to match the brightness of the second light emitting device GOLED with the brightness of the first light emitting device ROLED and the third light emitting device BOLED, thereby improving the brightness uniformity of the displayed image. Also, it is also possible to make the size of H2 the same as that of the through holes H1 and H3, and reduce the area of the second plate Cst2 where the through hole H2 is located, or change the relative position of the second plate Cst2 and the first plate Cst1, as long as the facing area between the first plate Cst1 and the second plate Cst2 can be reduced.

For example, the turn-on voltage of the second light emitting device GOLED is greater than the turn-on voltage of the first light emitting device ROLED and the third light emitting device BOLED. In order to charge the storage capacitor Cst of the second pixel circuit PC2 faster, so as to match the charging time of the storage capacitors Cst of the first pixel circuit PC1 and the third pixel circuit PC3, the storage capacitor Cst of the second pixel circuit PC2 may be reduced. Therefore, the through hole H2 may be larger than the through hole H1 and the through hole H3, that is, the area of the orthographic projection of the through hole H2 on the substrate SU is greater than the area of the orthographic projection of the through hole H1 and the through hole H3 on the substrate SU, thereby making the storage capacitor Cst of the second pixel circuit PC2 less than the storage capacitor Cst of the first pixel circuit PC1 and the third pixel circuit PC3 and, accordingly, shortening the charging time of the storage capacitor Cst of the second pixel circuit PC2, which is beneficial to enable the start-up time and timing of the light emitting device OLED to tend to be consistent and, accordingly, improves the display uniformity.

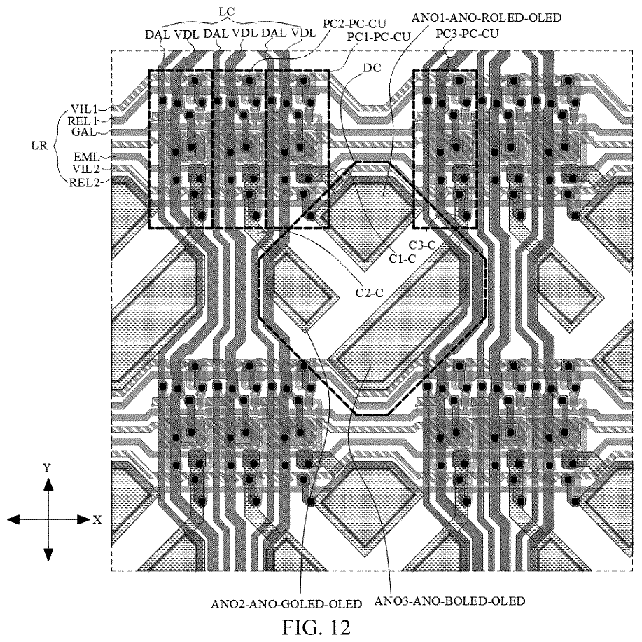

As shown in FIG. 11 and FIG. 12, in some embodiments of this disclosure, the pixel circuits of the same circuit unit CU may include a first pixel circuit PC1, a second pixel circuit PC2 and a third pixel circuit PC3 distributed along the row direction X.

The light emitting devices OLED of a same device unit DC may include a first light emitting device ROLED, a second light emitting device GOLED and a third light emitting device BOLED. The first electrode ANO of the first light emitting device ROLED is the first electrode ANO1, the first electrode ANO of the second light emitting device GOLED is the first electrode ANO2, and the first electrode ANO of the third light emitting device BOLED is the first electrode ANO3.

For the same device unit DC, the first electrode ANO1 of ROLED may be connected with a first pixel circuit PC1, the first electrode ANO2 of GOLED may be connected with a second pixel circuit PC2, and the first electrode ANO3 of BOLED may be connected with a third pixel circuit PC3. FIG. 11 and FIG. 12 only show the first electrode ANO of each light emitting device OLED, but do not show the light emitting functional layer EL and the second electrode CAT.

As shown in FIG. 11, the first pixel circuit PC1 and the second pixel circuit PC2 connected to the first light emitting device ROLED and the second light emitting device GOLED may be located in the same circuit unit CU, while the third pixel circuit PC3 connected to the third light emitting device BOLED may be located in another circuit unit CU, and the two circuit units CU are arranged adjacently in the row direction X.

Also, in some other embodiments of this disclosure, the pixel circuits PC connected to different light emitting devices OLED of the same device unit DC may also be located in the same circuit unit CU.

In addition, for the above-mentioned circuit unit CU with three pixel circuits PC, the row wiring harness LR connected thereto includes the same row wirings as the row wiring harness LR connected to one pixel circuit PC, and each row wiring harness LR may include a first reset signal line VIL1, a second reset signal line VIL2, a light emission control line EML, and a scanning line GAL. Also, since the three pixel circuits PC are distributed along the row direction, the column wiring harness LC includes three sets of column wirings, where each set of column wirings includes a data line DAL and a power supply line VDL, and the same set of column wirings is connected to a same pixel circuit PC.

As shown in FIG. 11, in some embodiments of this disclosure, in the light emitting devices OLED of the same device unit DC, the sizes of the first electrodes ANO of the first light emitting device ROLED, the second light emitting device GOLED and the third light emitting device BOLED may be different from each other, and the sizes of the openings APE defining the three light emitting devices OLED may also be different from each other. The area of the first electrode ANO3 of the third light emitting device BOLED is larger than the area of the first electrode ANO2 of the second light emitting device GOLED, and the area of the first electrode ANO2 of the second light emitting device GOLED is less than the area of the first electrode ANO1 of the first light emitting device ROLED. The area of the first electrode ANO refers to the area of its orthographic projection on the substrate SU.

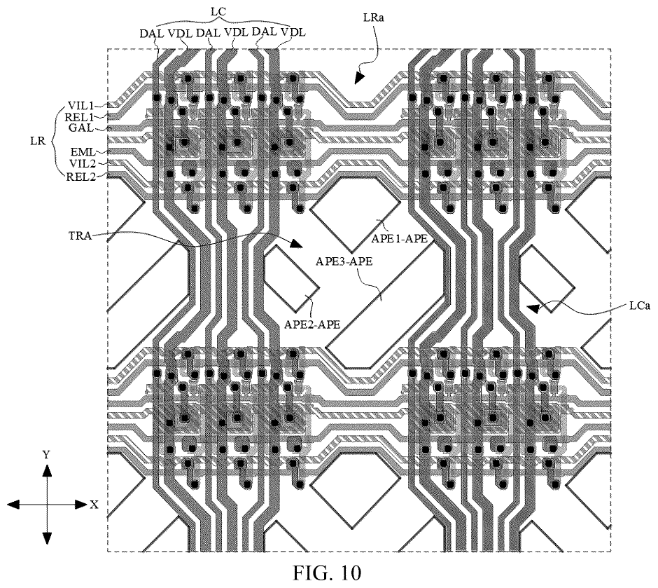

Correspondingly, as shown in FIG. 10 and FIG. 11, the opening APE defining the first light emitting device ROLED may be indicated as the first opening APE1, the opening APE defining the second light emitting device GOLED may be indicated as the second opening APE2, and the opening APE defining the third light emitting device BOLED may be indicated as the third opening APE3. The first opening APE1 is smaller than the second opening APE2, and the third opening APE3 is larger than the first opening APE1. The size of the opening APE refers to the area of its orthographic projection on the substrate SU.

In the orthographic projections of a transparent region TRA and its corresponding device unit DC on the substrate SU:

the transparent region TRA may include a first sub-region TRA1 and a second sub-region TRA2, where the first sub-region TRA1 extends in a first direction different from the row direction X and the column direction Y. The second sub-region TRA2 is located on one side of the first sub-region TRA1 and extends, along a second direction intersecting with the first direction, to adjoin the first sub-region TRA1, where the second direction is different from the row direction X and the column direction Y. For example, the first direction is perpendicular to the second direction.

Orthographic projections of the first electrode ANO1 of the first light emitting device ROLED and the first electrode ANO2 of the second light emitting device GOLED on the substrate SU are located on the same side of the first sub-region TRA1 and distributed on both sides of the second sub-region TRA2 along the first direction. The orthographic projection of the first electrode ANO3 of the third light emitting device BOLED on the driving layer PN is located on the side of the first sub-region TRA1 away from the second sub-region TRA2.

It should be noted that since the light emitting devices OLED are defined by the openings APEs, the distribution manner of the light emitting devices OLEDs is also the distribution manner of the openings APEs.

In order to ensure the light emitting range of the light emitting device OLED, the sizes of both the first electrode ANO and the opening APE defining the light emitting device OLED are limited and cannot be too small. Therefore, in order to avoid alleviating the shading of the light emitting device OLED by the row wiring harness LR and the column wiring harness LC by shrinking the opening APE and the first electrode ANO, it is possible to make the row wiring harness LR and the column wiring harness LC bend in the region between two adjacent device units DC, thereby not only alleviating the shading of the light emitting device OLED, but also avoiding shrinking the light emitting device OLED.

As shown in FIG. 9, the region where the row wiring harness LR is located between two adjacent circuit units CU may be recessed radially along a direction parallel to the substrate SU to form a row recess LRa, where the orthographic projection of the row recess LRa on the substrate SU is at least a part of the transparent region TRA, thereby enlarging the transparent region TRA by means of the row recesses LRa. The orthographic projection of the row recess LRa on the substrate SU at most partially coincides with the orthographic projection of an opening APE on the substrate SU. For example, the orthographic projection of the row recess LRa on the substrate SU and the orthographic projection of the opening APE on the substrate SU do not overlap with each other. Due to the existence of the row recess LRa, the row wiring harness LR at least does not block one light emitting device OLED. Also, the orthographic projection of the row recess LRa on the substrate SU and the orthographic projection of the opening APE on the substrate SU may also partially overlap with each other, but the area of the non-overlapping region therebetween is not less than 90% of the area of the orthographic projection of the opening APE on the substrate SU, thereby avoiding blocking the light emitting device OLED to emit light.

For example, the row wiring, in the row wiring harness LR, closest to the transparent region TRA may include row straight sections x1 and a row recess LRa alternately distributed along the row direction, where the row straight sections x1 may extend straight along the row direction, and the row recess LRa may include a row bottom section x3 and row climbing sections x2 connected to both ends of the row bottom section x3. The row bottom section x3 is connected with two row straight sections x1 adjacent to the row climbing sections x2 at both ends, and the row climbing section x2 forms a certain angle with the row straight section x1, where the angle is obtuse or acute. In FIG. 9, the row straight section x1, the row climbing section x2 and the row bottom section x3 are only shown in the first reset signal line VIL1, but the second reset line REL2 may also adopt this segmentation manner, which will not be detailed here.

In addition, in the same row wiring harness LR, in order to avoid the row recess LRa formed by bending the row wirings closest to the transparent region TRA, other row wirings may also be bent correspondingly. For example, as shown in FIG. 9, the second reset signal line VIL2 and the light emission control line EML may be recessed in the same direction as the first reset signal line REL2, where the second reset signal line VIL2 is recessed to the same depth as the row recess LRa, so that the distance between the second reset signal line VIL2 and the second reset line REL2 remains unchanged. The recess of the light emission control line EML may form a row recess LRa1 having a smaller depth than the row recess LRa. Also, the first reset signal line VIL1, the first reset line REL1 and the scanning line GAL are bent in the same direction to form a recess, and the direction of this recess is opposite to that of the second reset line REL2. The recessed region of the first reset signal line VIL1 may form another row recess LRa, and the recess of the scanning line GAL may form a row recess LRa2. The depth of the recess of the first reset line REL1 is the same as that of the row recess LRa of the first reset signal line VIL1, and the depth of the row recess LRa2 is less than that of the row recess LRa.

The depth of the recess above refers to the distance between the row bottom section x3 and the row straight section x1 in the column direction Y.

The region where the column wiring harness LC is located between two adjacent circuit units CU may be recessed radially along a direction parallel to the substrate SU to form a column recess LCa, where the orthographic projection of the column recess LCa on the substrate SU is at least a part of the transparent region TRA, thereby enlarging the transparent region TRA by means of the column recesses LCa. The orthographic projection of the column recess LCa on the substrate SU at most partially coincides with the orthographic projection of an opening APE on the substrate SU. For example, the orthographic projection of the column recess LCa on the substrate SU and the orthographic projection of the opening APE on the substrate SU do not overlap with each other. Due to the existence of the column recess LCa, the column wiring harness LC at least does not block one light emitting device OLED. Also, the orthographic projection of the column recess LCa on the substrate SU and the orthographic projection of the opening APE on the substrate SU may also partially overlap with each other, but the area of the non-overlapping region therebetween is not less than 90% of the area of the orthographic projection of the opening APE on the substrate SU, thereby avoiding blocking the light emitting device OLED to emit light.

For example, the column wiring, in the column wiring harness LC, closest to the transparent region TRA may include column straight sections y1 and a column recess LCa alternately distributed along the column direction, where the column straight sections y1 may extend straight along the column direction, and the column recess LCa may include a column bottom section y3 and column climbing sections y2 connected to both ends of the column bottom section y3. The column bottom section y3 is connected with two column straight sections y1 adjacent to the column climbing sections y2 at both ends, and the column climbing section y2 forms a certain angle with the column straight section y1, where the angle is obtuse or acute. In FIG. 9, the column straight section y1, the column climbing section y2 and the column bottom section y3 are only shown in the power supply line VDL of the first pixel circuit PC1, but the data line DAL may also adopt this segmentation manner, which will not be detailed here.

In addition, in the same column wiring harness LC, in order to avoid the column recess LCa formed by bending the column wiring closest to the transparent region TRA, other column wirings may also be bent correspondingly. For example: as shown in FIG. 9, in the same circuit unit CU:

the data line DAL and the power supply line VDL of a same pixel circuit PC are recessed in the same direction and have the same recess depth. Herein, the data line DAL of the first pixel circuit PC1 may be recessed in the same direction as its power supply line VDL, and the recess depth of the data line DAL of the first pixel circuit PC1 is the same as the column recess LCa, so that the distance between the data line DAL of the first pixel circuit PC1 and its power supply line VDL remains unchanged. In other words, the recess of the data line DAL of the first pixel circuit PC1 may form a column recess LCa1, and the depth of the column recess LCa1 is equal to that of the column recess LCa. Also, the data line DAL and the power supply line VDL of the second pixel circuit PC2 are recessed in the same direction as the data line DAL and the power supply line VDL of the third pixel circuit PC3, and the direction of such recess is opposite to that of the data line DAL and the power supply line VDL of the first pixel circuit PC1. The data line DAL of the second pixel circuit PC2 is recessed (in a direction opposite to the recess LCa formed by the power supply line VDL of the first pixel circuit PC1) to form another column recess LCa of the column wiring harness LC where it is located, and the data line of the second pixel circuit PC2 may be recessed to form a column recess LCa2 having a depth less than that of the column recess LCa1 and the column recess LCa. Also, the recessed direction of the data line DAL and the power supply line VDL of the second pixel circuit PC2 may also be replaced with a direction opposite to that shown in FIG. 9. In addition, the data line DAL and the power supply line VDL of a same pixel circuit PC may also be recessed in opposite directions. The recess depths of the data line DAL and the power supply line VDL of a same pixel circuit PC may also be different from each other.

The depth of the recess above refers to the distance between the column bottom section y3 and the column straight section y1 in the row direction X.

In some embodiments of this disclosure, as shown in FIG. 9 to FIG. 11, both the row recess LRa and the column recess LCa described above may be provided, and there are two row wiring harnesses LR and two column wiring harnesses LC around a same transparent region TRA.

Also, in some other embodiments of this disclosure, only one of the row recess LRa and the column recess LCa may be provided.

In some embodiments of this disclosure, as shown in FIG. 10, the orthographic projection of the opening APE corresponding to the first light emitting device ROLED on the substrate SU at most partially coincides with the orthographic projection of one column recess LCa on the substrate SU. The orthographic projection of the opening APE corresponding to the second light emitting device GOLED on the substrate SU at most partially coincides with the orthographic projection of one row recess LRa on the substrate SU. The orthographic projection of the opening APE corresponding to the third light emitting device BOLED on the substrate SU at most partially coincides with the orthographic projection of one row recess LRa on the substrate, and at most partially coincides with the orthographic projection of one column recess LCa on the substrate SU.

The shading relationship between the light emitting device OLED and the row and the column wiring harness LR, LC is described below.

As shown in FIG. 11, the first electrode ANO of each light emitting device OLED may be slightly larger than the opening APE defining the light emitting device OLED. Therefore, in the first electrodes ANO of the device unit DC corresponding to a same transparent region, the orthographic projection of at least one first electrode ANO on the substrate SU partially coincides with the orthographic projection of a row wiring harness LR on the substrate SU; the orthographic projection of at least one first electrode ANO on the substrate SU partially coincides with the orthographic projection of a column wiring harness LC on the substrate SU.

In some embodiments of this disclosure, as shown in FIG. 11, for the same device unit DC:
a partial region of the first electrode ANO1 of the first light emitting device ROLED covers the second reset control line REL2, but does not cover the second reset signal line VIL2; and a partial region of the boundary of the first electrode ANO1 extends in the same direction as the second reset control line REL2;
a partial region of the first electrode ANO2 of the second light emitting device GOLED covers its nearest power supply line VDL, but does not cover the data line DAL adjacent to the power supply line VDL; and a partial region of the boundary of the first electrode ANO2 extends in the same direction as the power supply line VDL; and
a partial region of the first electrode ANO3 of the third light emitting device BOLED covers the second reset control line REL2 of another row wiring harness LR (disposed opposite to the second reset control line REL2 covered by the first electrode ANO of the first light emitting device ROLED), but does not cover the second reset signal line VIL2; and a partial region of the boundary of the first electrode ANO3 extends in the same direction as the second reset control line REL2; also, a partial region of the first electrode ANO3 of the third light emitting device BOLED covers its nearest data line DAL, but does not cover the power supply line VDL adjacent to the data line DAL; and a partial region of the boundary of the first electrode ANO3 extends in the same direction as the data line DAL.

In addition, the first electrodes ANO of respective light emitting devices OLED of any device unit DC are connected to the pixel circuit PC through a connection part C. In the direction perpendicular to the substrate SU, the connection part C overlaps with the row wiring harness LR and the column wiring harness LC. Accordingly, through the connection of the connection part C, the first electrode ANO can be connected to the pixel circuit PC while corresponding to the transparent region TRA.

As shown in FIG. 12, in some embodiments of this disclosure, for the device unit DC shown in FIG. 12 including the first light emitting device ROLED, the second light emitting device GOLED and the third light emitting device BOLED, there are three corresponding connection parts C, including the first connection part C1, the second connection part C2 and the third connection part C3. Herein, the first electrode ANO1 may be connected with the first pixel circuit PC1 through the first connection part C1, the first electrode ANO2 may be connected with the second pixel circuit PC2 through the second connection part C2, and the first electrode ANO3 may be connected with the third pixel circuit PC3 through the third connection part C3. The first pixel circuit PC1 and the second pixel circuit PC2 are located in the same circuit unit CU, while the third pixel circuit PC3 is located in another circuit unit CU.

As shown in FIG. 12, the pixel circuits PC connected to the first connection part C1 and the second connection part C2 are located in the same circuit unit CU, and the pixel circuit PC connected to the third connection part C3 is located in a different circuit unit CU in the same row. In some embodiments, the length of the first connection part C1 in its extending direction is less than the length of the second connection part C2 in its extending direction, and the length of the second connection part C2 in its extending direction is less than the length of the third connection part C3 in its extending direction. Accordingly, the connection can be achieved between the pixel circuit PC and the first electrode ANO, while preventing the connection part C from being too long in the connection parts C connecting the light emitting devices OLED in the same device unit DC, and reducing the difficulty of wiring. The utilization of the space, where the connection part C may be arranged, can be maximized, and it is beneficial to reduce the length difference between the connection parts C, thereby improving the uniformity of the display effect.

The orthographic projection of the first connection part C1 and that of the second reset signal line VIL2 and the light emission control line EML on the substrate SU may have an overlapping region, but there is no overlap between the projection of the first connection part C1 and that of the second reset control line REL2 on the substrate SU, because the orthographic projection of the first electrode ANO1 and that of the second reset control line REL2 on the substrate SU overlap with each other, and the first connection portion C1 is located outside the first electrode ANO1.

The first connection portion C1 may include a first section connected to the first electrode ANO1 and a second section connected to the first pixel circuit PC1, where the first section and the second section are connected. The first section may extend in a direction different from the row direction X and the column direction Y, for example, in the second direction mentioned above. The second section may extend along the row direction X. There is an overlapping region between the projection of first section and that of the second reset signal line VIL2 and the light emission control line EML on the substrate SU. There is an overlapping region between the projection of the second section and that of the light emission control line EML on the substrate SU, and there is no overlapping region between the projection of the second section and that of the second reset signal line VIL2 on the substrate SU.

There is an overlapping region between the orthographic projection of the second connection part C2 and that of the second reset control line REL2, the second reset signal line VIL2, the light emission control line EML, the data line DAL and the power supply line VDL of the first pixel circuit PC1 on the substrate SU.

The second connection part C2 may include a first section connected to the first electrode ANO2 and a second section connected to the second pixel circuit PC2, where the first section and the second section are connected. The first section may extend in a direction different from the row direction X and the column direction Y, for example, in the second direction mentioned above. The second section may extend along the column direction Y. There is an overlapping region between the projection of the first section and that of the data line DAL and the power supply line VDL on the substrate SU. There is an overlapping region between the projection of the second section and that of the second reset control line REL2, the second reset signal line VIL2, and the light emission control line EML on the substrate SU, and the second section of the second connection portion C2 is located between the data line DAL of the first pixel circuit PC1 and the power supply line VDL of the second pixel circuit PC2.

There is an overlapping region between the orthographic projection of the third connection portion C3 and that of the second reset control line REL2, the second reset signal line VIL2, the light emission control line EML, the data line DAL and the power supply line VDL of the third pixel circuit PC3 on the substrate SU. The third pixel circuit PC3 is a third pixel circuit PC3 connected to the third connection part C3, and is located in a circuit unit CU adjacent to the circuit CU where the first pixel circuit PC1 and the second pixel circuit PC2 connected to the first connection part C1 and the second connection part C2 are located.

The third connection portion C3 may include a first section connected to the first electrode ANO3 and a second section connected to the third pixel circuit PC3, where the first section and the second section are connected. The first section may extend in a direction different from the row direction X and the column direction Y, for example, in the first direction mentioned above. The second section may extend along the column direction Y. There is an overlapping region between the projection of the first section and that of the power supply line VDL on the substrate SU. Since there is overlapping between the orthographic projection of the edge of the first electrode ANO3 and that of the data line DAL of the third pixel circuit PC3 connected thereto on the substrate SU, the first section of the third connection part C3 is located on one side of the data line DAL away from the first electrode ANO3, and there is no overlapping between the orthographic projection of the first section and that of the data line DAL on the substrate SU. There is an overlapping region between the orthographic projection of the second section and that of the second reset control line REL2, the second reset signal line VIL2, and the light emission control line EML on the substrate SU, and the second section of the third connection portion C3 is located between the power supply line VDL of the third pixel circuit PC3 connected thereto and the data line DAL of the second pixel circuit PC2 adjacent thereto.

For the display panel of this disclosure, in order to improve the light transmittance, the purpose of improving the brightness of the back display can be achieved by setting the thickness of the first electrode ANO of the light emitting device OLED, while ensuring the electrical properties of the first electrode ANO, so as to avoid affecting the normal operation of the light emitting device OLED.

For example, as shown in FIG. 1, in some embodiments of this disclosure, the first electrode ANO may include a first transparent conductive layer TA1, a conductive metal layer MET and a second transparent conductive layer TA2. The material of the first transparent conductive layer TA1 and the second transparent conductive layer TA2 is indium tin oxide, and the material of the conductive metal layer MET is silver. The thickness of the conductive metal layer MET is not less than 200 Å and not greater than 300 Å. The thicknesses of the first transparent conductive layer TA1 and the second transparent conductive layer TA2 are not less than 80 Å and not greater than 100 Å

In addition, the material of the second electrode CAT may be magnesium-silver alloy, and its thickness is not less than 13 nm and not greater than 15 nm.

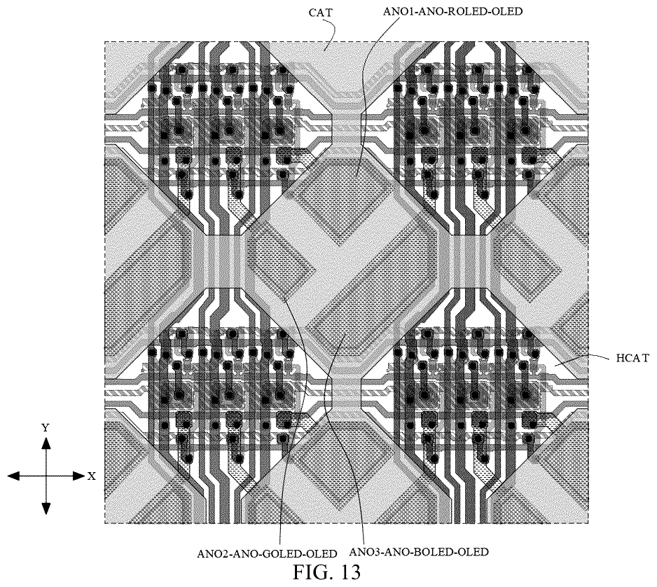

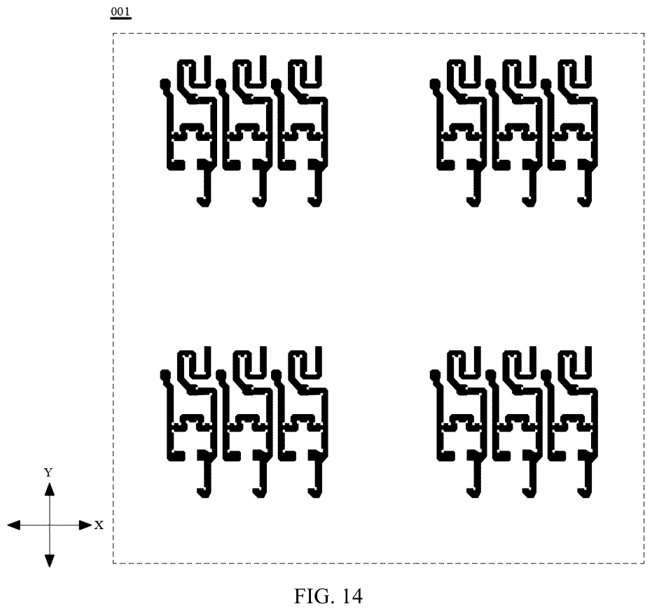

In order to further improve light transmittance, as shown in FIG. 13, in some embodiments of this disclosure, the second electrode CAT may be a continuous whole-layer structure, so that respective light emitting devices OLED share the same second electrode CAT. A light-transmitting hole HCAT may be opened in the region of the second electrode CAT corresponding to a region other than the opening APE, and the opening APE may still need to be covered by the second electrode CAT, thereby ensuring that the light emitting device OLED can emit light normally. The light transmittance of the display panel can be improved by means of the light-transmitting hole HCAT, thereby improving the effect of transparent display. The number of light-transmitting hole(s) HCAT may be multiple, and the specific number and shape thereof are not particularly limited here, as long as the light emission of the light emitting device OLED is not affected.

It should be noted that since respective light emitting devices OLED share the second electrode CAT, the light-transmitting hole HCAT should not cut off the second electrodes CAT corresponding to different light emitting devices OLED, and the second electrode CAT may still be a conductive overall structure, only partially hollowed out, so that the second power signal VSS can be simultaneously input to each OLED by the peripheral circuit through the second electrode CAT.

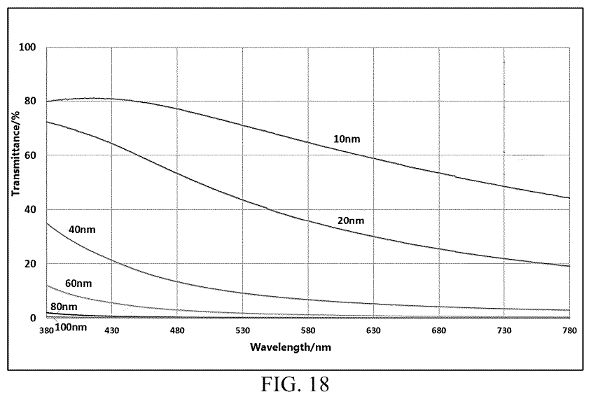

As shown in FIG. 18, FIG. 18 shows the change trend of the light transmittance under the conductive metal layer MET having different thicknesses and the light having different wavelengths. The abscissa is the wavelength of the light, and the ordinate is the light transmittance. According to the test results obtained in FIG. 16, it can be seen that a very good function of semi-transmitting and semi-reflecting can be achieved under the thickness of the conductive metal layer MET being around 200 Å.

In addition, both the planarization layer PLN and the pixel definition layer PDL may use resin or other materials with high light transmittance (light transmittance not less than 86%). It has been verified by experiments that, combined with the above-mentioned materials and thicknesses of the first electrode ANO and the second electrode CAT, the reflectance of the first electrode ANO is about 53%, and the light transmittance is about 40%. The brightness of the front display can reach 40%-45%, the brightness of the back display can reach 60%, and the color gamut of the front and back can reach 99%.

Embodiments of this disclosure further provide a method for manufacturing a display panel. The display panel may be the display panel in any of the above embodiments, and its structure will not be described in detail here. The manufacturing method may include steps S110 and S120.

In step S110, a driving layer is formed on one side of a substrate, where the driving layer includes multiple circuit units distributed in an array, multiple row wiring harnesses, and multiple column wiring harnesses; the circuit unit includes multiple pixel circuits; the row wiring harness includes multiple row wirings distributed at intervals along a column direction, the column wiring harness includes multiple column wirings distributed at intervals along a row direction; the circuit units in a same row are connected through one of the row wiring harnesses, and the circuit units in a same column are connected through one of the column wiring harnesses; orthographic projections of the row wiring harnesses and the column wiring harnesses on the substrate cross and separate multiple transparent regions, and a region of the driving layer corresponding to the transparent region is a transparent structure.

In step S120, a light emitting layer, including multiple device units distributed in an array, is formed on a surface of the driving layer away from the substrate, where the device units correspond to the transparent regions; the device unit includes multiple light emitting devices distributed at intervals, each of the light emitting devices is connected to one of the pixel circuits; the light emitting device includes a first electrode, a light emitting functional layer and a second electrode stacked sequentially in a direction away from the substrate, and the first electrode and the second electrode are transparent structures.

Since the details of the structure involved in each step of the above-mentioned manufacturing method have been described in detail in the embodiments of the display panel above, the details and beneficial effects thereof will not be described in detail here.

It should be noted that although the various steps of the manufacturing method in this disclosure are described in a specific order in the drawings, this does not require or imply that these steps must be performed in this specific order, or that all shown steps must be performed to achieve the desired result. Additionally or alternatively, certain steps may be omitted, multiple steps may be combined into one step for execution, and/or one step may be decomposed into multiple steps for execution.

Embodiments of this disclosure further provide a display device, which may include the display panel in any of the above embodiments. The specific structure and beneficial effects of the display panel have been described in detail in the embodiments of the display panel above, and will not be described in detail here. The display device of this disclosure may be used in electronic devices with image display functions such as mobile phones, tablet computers, and televisions, and will not be listed here.

Other embodiments of this disclosure will be readily apparent to those skilled in the art from consideration of the specification and practice of the invention disclosed herein. This application is intended to cover any modification, use or adaptation of this disclosure, and these modifications, uses or adaptations follow the general principles of this disclosure and include common knowledge or conventional technical means in the technical field not disclosed in this disclosure. The specification and examples are to be considered exemplary only, with the true scope and spirit of the disclosure indicated by the appended claims.

1. A display panel, comprising:
a substrate;
a driving layer, arranged on one side of the substrate and comprising multiple circuit units distributed in an array, multiple row wiring harnesses, and multiple column wiring harnesses; wherein the circuit unit comprises multiple pixel circuits; the row wiring harness comprises multiple row wirings distributed at intervals along a column direction, the column wiring harness comprises multiple column wirings distributed at intervals along a row direction; the circuit units in a same row are connected through one of the row wiring harnesses, and the circuit units in a same column are connected through one of the column wiring harnesses; orthographic projections of the row wiring harnesses and the column wiring harnesses on the substrate cross and separate multiple transparent regions, and a region of the driving layer corresponding to the transparent region is a transparent structure; and
a light emitting layer, arranged on a surface of the driving layer away from the substrate, and comprising multiple device units distributed in an array; wherein the device units correspond to the transparent regions; the device unit comprises multiple light emitting devices distributed at intervals, each of the light emitting devices is connected to one of the pixel circuits; the light emitting device comprises a first electrode, a light emitting functional layer and a second electrode stacked sequentially in a direction away from the substrate, and the first electrode and the second electrode are transparent structures.

2. The display panel according to claim 1, wherein the light emitting layer further comprises a pixel definition layer separating respective ones of the light emitting devices, and the pixel definition layer has openings defining the respective ones of the light emitting devices;
a region of the row wiring harness located between adjacent two of the circuit units is recessed radially to form a row recess, an orthographic projection of the row recess on the substrate is at least a part of the transparent region, and an orthographic projection of one of the openings on the substrate at most partially coincides with the orthographic projection of the row recess on the substrate.

3. The display panel according to claim 1, wherein the light emitting layer further comprises a pixel definition layer separating respective ones of the light emitting devices, and the pixel definition layer has openings defining the respective ones of the light emitting devices;
a region of the column wiring harness located between adjacent two of the circuit units is recessed radially to form a column recess, an orthographic projection of the column recess on the substrate is at least a part of the transparent region, and an orthographic projection of one of the openings on the substrate at most partially coincides with the orthographic projection of the column recess on the substrate.

4. The display panel according to claim 1, wherein the light emitting layer further comprises a pixel definition layer separating respective ones of the light emitting devices, and the pixel definition layer has openings defining the respective ones of the light emitting devices;
a region of the row wiring harness located between adjacent two of the circuit units is recessed radially to form a row recess, an orthographic projection of the row recess on the substrate is at least a part of the transparent region, and an orthographic projection of one of the openings on the substrate at most partially coincides with the orthographic projection of the row recess on the substrate; and
a region of the column wiring harness located between adjacent two of the circuit units is recessed radially to form a column recess, an orthographic projection of the column recess on the substrate is at least a part of the transparent region, and an orthographic projection of one of the openings on the substrate at most partially coincides with the orthographic projection of the column recess on the substrate.

5. The display panel according to claim 4, wherein one of the device units comprises three light emitting devices with different light emitting colors, and the first electrodes of the three light emitting devices have different sizes.

6. The display panel according to claim 5, wherein the one of the device units comprises a first light emitting device emitting green light, a second light emitting device emitting red light, and a third light emitting device emitting blue light;
an area of the first electrode of the third light emitting device is larger than an area of the first electrode of the first light emitting device, and the area of the first electrode of the first light emitting device is larger than an area of the first electrode of the second light emitting device.

7. The display panel according to claim 6, wherein an orthographic projection of the opening corresponding to the first light emitting device on the substrate at most partially coincides with the orthographic projection of the column recess on the substrate;
an orthographic projection of the opening corresponding to the second light emitting device on the substrate at most partially coincides with the orthographic projection of the row recess on the substrate;
an orthographic projection of the opening corresponding to the third light emitting device on the substrate at most partially coincides with the orthographic projection of the row recess on the substrate, and at most partially coincides with the orthographic projection of the column recess on the substrate.

8. The display panel according to claim 1, wherein, among the first electrodes of the device unit corresponding to one of the transparent regions, an orthographic projection of at least one of the first electrodes on the substrate partially coincides with an orthographic projection of one of the row wiring harnesses on the substrate; and an orthographic projection of at least one of the first electrodes on the substrate partially coincides with an orthographic projection of one of the column wiring harnesses on the substrate.

9. The display panel according to claim 6, wherein in orthographic projections of one of the transparent regions and a corresponding one of the device units on the substrate:
the one of the transparent regions comprises a first sub-region and a second sub-region, the first sub-region extends along a first direction different from the row direction and the column direction; the second sub-region is located on one side of the first sub-region, and extends, along a second direction intersecting with the first direction, to adjoin the first sub-region, where the second direction is different from the row direction and the column direction;
orthographic projections of the first electrode of the first light emitting device and the first electrode of the second light emitting device on the driving layer are located on a same side of the first sub-region, and are distributed along the first direction on two sides of the second sub-region; and an orthographic projection of the first electrode of the third light emitting device on the driving layer is located on one side of the first sub-region away from the second sub-region.

10. The display panel according to claim 1, wherein the row wiring harness comprises multiple row wirings, and the row wirings comprise scanning lines;
the column wiring harness comprises multiple column wirings, and the column wirings comprise data lines.

11. The display panel according to claim 1, wherein pixel circuits connected to different light emitting devices of a same one of the device units are located in different ones of the circuit units.

12. The display panel according to claim 11, wherein the pixel circuits connected to different light emitting devices of a same one of the device units are located in a same row of the circuit units.

13. The display panel according to claim 12, wherein the first electrode of each light emitting device of any one of the device units is connected to one of the pixel circuits through a connection part;
the first electrode of a first light emitting device is connected to one of the pixel circuits through a first connection part; the first electrode of a second light emitting device is connected to one of the pixel circuits through a second connection part, and the first electrode of a third light emitting device is connected to one of the pixel circuits through a third connection part;
pixel circuits connected to the first connection part and the second connection part are located in a same one of the circuit units, which is different from, but in a same row as, one of the circuit units where the one of the pixel circuits connected to the third connection part is located in; and
a length of the first connection part in its extending direction is less than a length of the second connection part in its extending direction, and the length of the second connection part in its extending direction is less than a length of the third connection part in its extending direction.

14. The display panel according to claim 1, wherein the driving layer comprises:
an active layer, provided on one side of the substrate;
a first gate insulating layer, covering the active layer and the substrate;
a gate, provided on a surface of the first gate insulating layer away from the substrate;
a second gate insulating layer, covering the gate and the first gate insulating layer;
an interlayer dielectric layer, covering the second gate insulating layer;
a source-drain layer, provided on a surface of the interlayer dielectric layer away from the substrate; and
a planarization layer, covering the source-drain layer and the interlayer dielectric layer;
wherein the display panel further comprises:
an encapsulation layer, covering the light emitting layer; and
a touch layer, provided on a surface of the encapsulation layer away from the substrate.

15. The display panel according to claim 1, wherein the first electrode comprises a first transparent conductive layer, a conductive metal layer and a second transparent conductive layer sequentially stacked in the direction away from the substrate, a resistivity of the conductive metal layer is less than resistivities of the first transparent conductive layer and the second transparent conductive layer; and
a thickness of the conductive metal layer is not less than 200 Å and not greater than 300 Å.

16. The display panel according to claim 15, wherein thicknesses of the first transparent conductive layer and the second transparent conductive layer are not less than 80 Å and not greater than 100 Å.

17. The display panel according to claim 1, wherein a thickness of the second electrode is not less than 13 nm and not greater than 15 nm.

18. A method for manufacturing a display panel, comprising:
forming a driving layer on one side of a substrate, wherein the driving layer comprises multiple circuit units distributed in an array, multiple row wiring harnesses, and multiple column wiring harnesses; the circuit unit comprises multiple pixel circuits; the row wiring harness comprises multiple row wirings distributed at intervals along a column direction, the column wiring harness comprises multiple column wirings distributed at intervals along a row direction; the circuit units in a same row are connected through one of the row wiring harnesses, and the circuit units in a same column are connected through one of the column wiring harnesses; orthographic projections of the row wiring harnesses and the column wiring harnesses on the substrate cross and separate multiple transparent regions, and a region of the driving layer corresponding to the transparent region is a transparent structure; and
forming, on a surface of the driving layer away from the substrate, a light emitting layer comprising multiple device units distributed in an array, wherein the device units correspond to the transparent regions; the device unit comprises multiple light emitting devices distributed at intervals, each of the light emitting devices is connected to one of the pixel circuits; the light emitting device comprises a first electrode, a light emitting functional layer and a second electrode stacked sequentially in a direction away from the substrate, and the first electrode and the second electrode are transparent structures.

19. A display device, comprising a display panel, wherein the display panel comprises:
a substrate;
a driving layer, arranged on one side of the substrate and comprising multiple circuit units distributed in an array, multiple row wiring harnesses, and multiple column wiring harnesses; wherein the circuit unit comprises multiple pixel circuits; the row wiring harness comprises multiple row wirings distributed at intervals along a column direction, the column wiring harness comprises multiple column wirings distributed at intervals along a row direction; the circuit units in a same row are connected through one of the row wiring harnesses, and the circuit units in a same column are connected through one of the column wiring harnesses; orthographic projections of the row wiring harnesses and the column wiring harnesses on the substrate cross and separate multiple transparent regions, and a region of the driving layer corresponding to the transparent region is a transparent structure; and
a light emitting layer, arranged on a surface of the driving layer away from the substrate, and comprising multiple device units distributed in an array; wherein the device units correspond to the transparent regions; the device unit comprises multiple light emitting devices distributed at intervals, each of the light emitting devices is connected to one of the pixel circuits; the light emitting device comprises a first electrode, a light emitting functional layer and a second electrode stacked sequentially in a direction away from the substrate, and the first electrode and the second electrode are transparent structures.
